(19) United States
(12) Patent Application Publication
(10) Pub. No.: US 2006/0150055 A1
(43) Pub. Date: Jul. 6, 2006

(54) Adaptive information delivery system using FEC feedback

(75) Inventors: Fabrice Michel Raymond Quinard, Los Gatos, CA (US); Robert James Fanfelle, Redwood City, CA (US); Paul Alan Lind, Santa Cruz, CA (US)

Correspondence Address: PATENT LAW OFFICE OF DAVID G. BECK, P. O. BOX 1146, MILL VALLEY, CA, 94942, US

(73) Assignee: Terayon Communication Systems, Inc., Santa Clara, CA (US)

(21) Appl. No.: 11/031,391

(22) Filed: Jan. 6, 2005

(51) Int. Cl. H03M 13/00

(52) U.S. Cl. 714/752

(57) ABSTRACT

A method and apparatus for optimizing the data transfer rate over a transport layer (i.e., communication link) such as the Internet is provided. Initially the data is prepared for transmission by a transfer rate controller, then the data is encoded by a Forward Error Correction (FEC) encoder. After the data has been transferred over the transport layer, the quality of the data transfer link is assessed by an FEC decoder that determines if any errors occurred during data transfer and if errors are detected, the magnitude of the errors (i.e., FEC-correctable packets, FEC-uncorrectable packets). This information is used to generate a feedback message which is used by the transfer rate controller to adjust and optimize the data transfer rate for the link quality as determined at that point in time. By continually monitoring and assessing link quality and providing feedback to the transfer rate controller, the transfer rate can be continually adapted to the varying link quality. In addition to generating feedback used by the transfer rate controller to optimize data transfer rate, the FEC decoder can generate feedback that is used by the FEC encoder to optimize the FEC algorithm. If desired, feedback from the FEC decoders within the link layer demodulator and/or feedback from the receiver can be used to augment the feedback generated by the FEC decoder.

### FIELD OF THE INVENTION

The present invention relates generally to data transmission systems and, more particularly, to a method and apparatus for improving the quality of information transmitted via a data transmission system.

### BACKGROUND OF THE INVENTION

The Internet was originally developed for transferring bulk data, such as files and email, in small segments commonly referred to as packets. Although it was intended to be a best-effort delivery system, never guaranteeing individual packet delivery, it was nevertheless designed to be extremely resilient, providing a means for routing around individual components upon their failure.

In recent years the Internet has enjoyed immense popularity, in part due to the development of a variety of high-speed data transfer technologies. Even using such high-speed technologies, transferring a large data file (e.g., lengthy document, video file, audio file, etc.) can still be very time consuming. For example, downloading a movie over a standard DSL line typically requires several hours. Accordingly a variety of techniques have been developed, or are under development, in an attempt to minimize the limitations associated with data transfer. A fundamental technique in this area is data compression, which reduces the size of the file/information being transferred.

In developing data transfer technologies, the developer must be mindful of the type of data being transferred as well as any timeliness requirements placed on the data. Many types of data must be transferred perfectly, without alteration (e.g. documents, spreadsheets). This data may be compressed, but the compression algorithm must be completely reversible in order to exactly recover the original data file. Media files (e.g. audio, video, pictures, etc.), however, can be compressed with lossy-compression algorithms that actually throw away information to reduce file size, at the expense of ultimate quality. Therefore, a tradeoff between perceived quality and file size can be made. While quality may be degraded with lossy-compression techniques, the amount of compression achievable is far higher than with lossless compression.

Timeliness refers to whether or not a real-time data stream is required. Although some data is not time-sensitive, a phone or video conversation takes place in real-time and therefore requires timely data delivery. It is also common to play audio or video files in real-time from a remote server. In these approaches the data is sent in packets, with only enough of the data being sent initially to get the sound or image started. Over time, the data file is played-out at the server and sent to the client ‘just in time’ for presentation.

Although the loss of any significant percentage of the data packets leads to an unacceptable quality level in the delivered data (i.e., video and/or audio data), this is typically not a problem with data transferred over a dedicated channel (e.g., cable channel, disc player, etc.). In contrast, data transferred over the Internet suffers from much higher error rates, the higher error rates primarily due to varying levels of Internet traffic, varying hardware capabilities (e.g., link speeds), and individual component/technology failures. Additionally, one or more of the components which make up the underlying Internet network may be subjected to any of a variety of noise or interference sources.

A variety of companies have developed, or are currently developing, services to be delivered to the end user over the Internet (e.g., on-demand movies, interactive video, games, video conferencing, commercial voice services, etc.). In order for such services to be viable, data transmission must be both reliable and of very high quality. Although quality and reliability can typically be achieved by over-provisioning the resources (e.g., transmission redundancy, slow data rates, data transfer verification at the endpoint, etc.), such approaches are both inconvenient and very inefficient, both in terms of transfer rates and overall system usage. Accordingly a variety of adaptation techniques have been developed which can be used to mitigate variations in the hardware, re-route data transfer to avoid congestion, protect against variations in error and available rate, and re-negotiate connection parameters. Typical applications designed to adapt to changing network conditions use any of a variety of encoding, compression, bandwidth smoothing, rate shaping, and error control techniques.

One commonly employed adaptation scheme varies the source rate of the video and/or audio data. Given the direct correlation between source rate and transmitted data quality, high source rates yield desirable quality levels. Unfortunately in the presence of network congestion, high source rates also lead to the loss of data packets, resulting in severely degraded quality if not total data stream failure. As rate reduction can be used to reduce or eliminate congestion, rate adaptive techniques must strike a balance between quality loss due to reduced source rates with the potential for loss or total failure from higher source rates.

Forward Error Correction (FEC) techniques add redundant data to a media stream, thus allowing packet losses to be repaired at the receiver without requiring either contact with the sender or retransmission of lost data. As data retransmission is not used with this technique, its primary advantage is end-to-end speed. The primary tradeoff with FEC schemes is providing sufficient redundant data to compensate for expected packet losses while not providing too much redundant data which adversely affects transfer speed. By varying the amount of applied FEC based on feedback from the client, the technique can be optimized for varying network conditions.

Another adaptation technique, referred to as unequal loss protection, varies the amount of FEC protection encoded by the sender based on the loss-sensitivity of that information. Thus important data (e.g., lower order coefficients of discrete cosine transformation (DCT), critical timing information) are given more protection than less important data.

Although a variety of rate adaptive systems have been designed, these systems are typically designed to adapt based on packet loss at the client system, resulting in the end-user periodically experiencing periods of unacceptable data quality (e.g., drop-outs, frozen frames, etc.). Accordingly, what is needed in the art is a rate adaptive system that provides high speed data transfer while achieving optimal quality levels, the system capable of adapting before packet loss is experienced. The present invention provides such a method and apparatus.

### SUMMARY OF THE INVENTION

The present invention provides a method and apparatus for optimizing the data transfer rate over the Internet, a wireless network, a satellite based network, a dedicated channel or other communication link. Initially the data is prepared by a transfer rate controller (e.g., encoded, shaped, etc.) and then an FEC algorithm is applied to the data. After the data has been transferred, the quality of the data transfer link is assessed by an application layer FEC decoder that determines if any errors occurred during data transfer and if errors are detected, the magnitude of the errors (i.e., FEC-correctable blocks, FEC-uncorrectable blocks). This information is used to generate a feedback message which is used by the transfer rate controller to adjust and optimize the data transfer rate for the link quality as determined at that point in time. Optimal use results when feedback is sent to the source before end-user data corruption has occurred. By continually monitoring and assessing link quality and providing feedback to the transfer rate controller, the transfer rate can be continually adapted to the varying link quality.

In one embodiment of the invention, in addition to generating feedback used by the transfer rate controller to optimize data transfer rate, the application layer FEC decoder generates feedback that is used by the FEC encoder to optimize the FEC algorithm.

In another embodiment of the invention, the receiver generates feedback which augments the feedback generated by the FEC decoder and used by the transfer rate controller to vary the data transfer rate.

In another embodiment of the invention, a physical layer FEC decoder determines if there are any FEC-correctable blocks and/or FEC-uncorrectable blocks and uses this information to generate the feedback message used by the transfer rate controller to adjust and optimize the data transfer link.

In another embodiment of the invention, a physical layer FEC decoder generates feedback which augments the feedback generated by the application layer FEC decoder and used by the transfer rate controller to vary the data transfer rate.

A further understanding of the nature and advantages of the present invention may be realized by reference to the remaining portions of the specification and the drawings.

### BRIEF DESCRIPTION OF THE DRAWINGS

FIG. 1 graphically illustrates the varying error threshold common in a communication link such as the Internet;

FIG. 2 graphically illustrates transfer rate variations responsive to monitored packet loss at the end-user system in accordance with the prior art;

FIG. 3 graphically illustrates the effects of an FEC algorithm on the varying transfer rate shown in FIG. 2;

FIG. 4 is an illustration of the invention;

FIG. 5 graphically illustrates transfer rate variations responsive to monitored FEC-correctable and FEC-uncorrectable blocks in accordance with the invention;

FIG. 6 is an illustration of an alternate embodiment in which feedback from the FEC decoder is used by both the transfer rate controller and the FEC encoder;

FIG. 7 is an illustration of an alternate embodiment in which both the FEC decoder and the data receiver provide feedback;

FIG. 8 is an illustration of an alternate embodiment of the invention based on the embodiment shown in FIG. 4, with the addition of feedback from at least one FEC decoder within the demodulator of a link layer subsystem;

FIG. 9 is an illustration of an alternate embodiment of the invention based on the embodiment shown in FIG. 6, with the addition of feedback from at least one FEC decoder within the demodulator of a link layer subsystem;

FIG. 10 is an illustration of an alternate embodiment of the invention based on the embodiment shown in FIG. 7, with the addition of feedback from at least one FEC decoder within the demodulator of a link layer subsystem;

FIG. 11 is an illustration of a video-on-demand system using the present invention;

FIG. 12 is an illustration of the data format used between the streaming video server and the digital stream management system of FIG. 11;

FIG. 13 is an illustration of the two processing steps used on the encoding side of the protocol that transports the FEC-encoded data between the sender and the receiver;

FIG. 14 is an illustration of the two processing steps used on the decoding side of the protocol that transports the FEC-encoded data between the sender and the receiver; and

FIG. 15 is an illustration of the intermediate packet used in the protocol that transports the FEC-encoded data between the sender and the receiver.

### DESCRIPTION OF THE SPECIFIC EMBODIMENTS

Data channels are subject to errors arising from a variety of time-varying sources such as external noise or interference, router congestion, link congestion, etc., all of which lead to a time varying error rate associated with the channel. This time varying error rate controls the allowable data transfer rate of the channel. If the rate of data transfer over the channel is low enough, the data can be transferred error-free. As the transfer rate over the channel is increased, however, eventually the rate will be high enough that the error characteristics of the channel will cause data to be corrupted or lost. Thus the error rate of the channel establishes an error threshold.

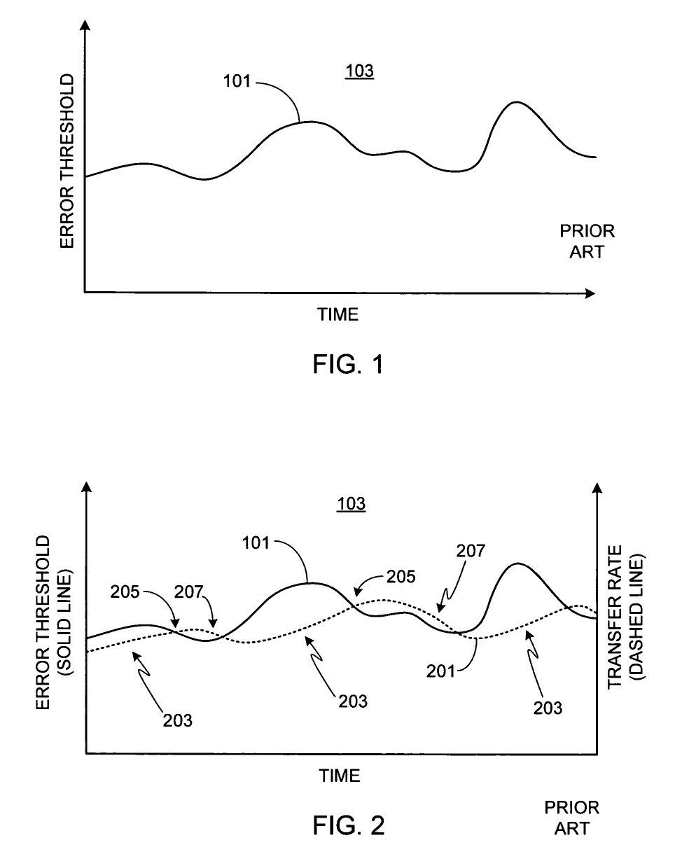

FIG. 1 graphically illustrates the concept of an error threshold (i.e., line 101). As shown, the error threshold varies with time. As long as the transfer rate remains below error threshold 101, the data transfer is error-free. Each time the transfer rate exceeds threshold 101, passing into zone 103, data is lost or corrupted. The level of data corruption or loss is determined both by the length of time that the transfer rate remains over threshold 101 and the amount by which the transfer rate exceeds threshold 101.

Given the time varying nature of the error threshold, a well designed data transfer system will controllably vary the data transfer rate, maximizing the transfer rate to the level permitted by the channel's error threshold, thereby optimizing the quality of the transferred data. FIG. 2 graphically illustrates the concept of a time varying transfer rate (i.e., dashed line 201) in accordance with the prior art. As shown, the data transfer system continually ‘tests’ the channel's capabilities in order to determine the maximum allowable data transfer rate as given by the channel's error threshold (line 101). More specifically, prior art systems monitor the data received by the end-user, providing feedback to the transfer rate controller. As long as the end-user is receiving all of the transferred data packets, the transfer rate controller continues to increase the transfer rate, thus attempting to optimize the transfer rate (e.g., portion 203 of line 201). Each time the data receiver determines that data has been lost during data transfer, i.e., that the transfer rate has exceeded the error threshold (e.g., location 205), feedback is provided to the transfer rate controller that directs the rate controller to decrease the transfer rate. The transfer rate is then decreased (e.g., portion 207 of line 201) until the system is no longer experiencing packet loss. Unfortunately until the transfer rate is lowered to a level below the error threshold, the data sent to the end-user is severely degraded, typically to the point of being unacceptable (e.g., audio drop-outs, video drop-outs, etc.).

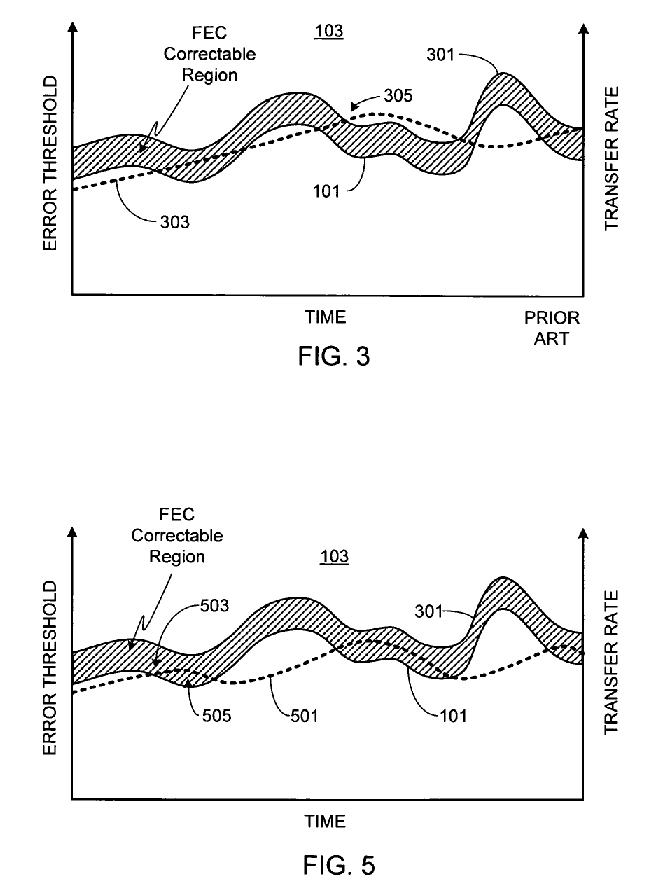

FEC techniques, which provide a means for replacing data packets lost during data transfer, allow the data transfer rate to exceed the channel's error threshold without the end-user experiencing any data degradation. The extent to which the data transfer rate can exceed the error threshold depends on the amount of redundant data included in the data stream. FIG. 3 illustrates the effects of applying FEC techniques to the rate adaptation scheme of FIG. 2. As shown, the FEC techniques increase the error threshold from the original level (i.e., line 101) to a higher level (i.e., line 301). Accordingly if the data transfer rate (i.e., line 303) exceeds threshold 101, but remains below threshold 301, lost data packets can be replaced. Unfortunately as the feedback mechanism of the prior art system monitors lost data packets and cannot differentiate between FEC-corrected and FEC-uncorrected packets, the prior art system will still occasionally exceed the channel's FEC enhanced error threshold (e.g., location 305), thus leading to unacceptable data loss.

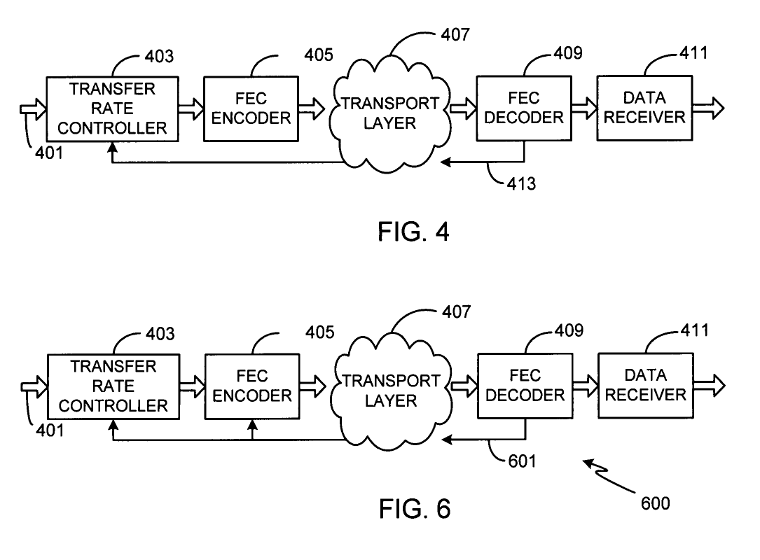

FIG. 4 is a block diagram illustrating the invention. As shown, after the data 401 (i.e., video data, audio data, non-multimedia data, etc.) is prepared for transmission by transfer rate controller 403, the prepared data is encoded by a Forward Error Correction (FEC) encoder 405. The data is then sent via transport layer 407 (i.e., a communication link such as the Internet, a dedicated channel, etc.) through an FEC decoder 409 and a data receiver 411 before being forwarded to the end-point destination. It will be appreciated that FEC decoder 409 can be separate from, or contained within, data receiver 411. FEC decoder 409 determines if there are any errors in the transferred data and if there are, corrects the lost data to the extent possible prior to sending the data on to receiver 411. Additionally, and in accordance with the invention, FEC decoder 409 provides feedback 413 to transfer rate controller 403 regarding the quality of the link provided by transport layer 407, i.e., error occurrence, error quantity, and/or error type (e.g., FEC-correctable packets, FEC-uncorrectable packets). As a result of feedback 413, transfer rate controller 403 adjusts the transfer rate, preferably before exceeding the ability of FEC decoder 409 to correct the errors. Accordingly the data forwarded by receiver 411 to the end-point typically is of a higher perceived quality since the system is able to minimize any occurrences of unrecoverable packet loss.

FIG. 5 illustrates the effects of applying the rate adaptation scheme of the present invention to the error threshold previously described. As the invention utilizes feedback from the FEC decoder, the system can distinguish between data that is transferred without experiencing any loss (i.e., transfer rate below error threshold 101) and data that was corrected by the FEC algorithm (i.e., transfer rate below FEC enhanced error threshold 301). Accordingly the transfer rate (i.e., dashed line 501) begins to adapt as soon as it exceeds error threshold 101 (i.e., location 503). As a result, the FEC algorithm is able to restore the lost data (e.g., portion 505), thus minimizing if not altogether eliminating unacceptable data loss.

In the description of the invention, the terms data rate controller (i.e., controller 403) and data receiver (i.e., receiver 411) are used since the exact nature of the transfer rate controller and the data receiver depends upon the type of data 401 as well as the type of compression technique employed to transfer the data over the transport layer. It is well understood by those of skill in the art that while some data types (e.g., video data, audio data) lend themselves to lossy compression techniques, other data types (e.g., documents, spreadsheets, etc.) require that the full, unaltered bit stream be transferred, or require the use of lossless compression techniques. In addition, if the data stream is being played out in real-time, the information must be sent in a timely manner. For non-real-time data, however, the data-stream can simply be reduced in rate by slowing the transmission of packets using a rate-shaping device.

FIG. 6 is a block diagram illustrating another embodiment of the invention. As in the previous embodiment, the system includes a transfer rate controller 403, an FEC encoder 405, a transport layer 407 (e.g., a communication link such as the Internet), an FEC decoder 409 and a receiver 411. In this embodiment, FEC decoder 409 not only provides feedback 601 to transfer rate controller 403 in order to adjust the data transfer rate, but also to FEC encoder 405 in order to adjust the amount of redundant data being added to the encoded data stream. Accordingly system 600 compensates for variations in the error rate both with variations in data transfer rate and variations in the overall resiliency of the encoded data. Thus if the error rate is relatively flat, i.e., only minor observed variations, the system can operate at a high transfer rate with minimal FEC encoding. Conversely, if the error rate is varying widely, or quickly, the system can operate at a reduced transfer rate with a higher level of FEC encoding, thus minimizing lost packets and maintaining data fidelity.

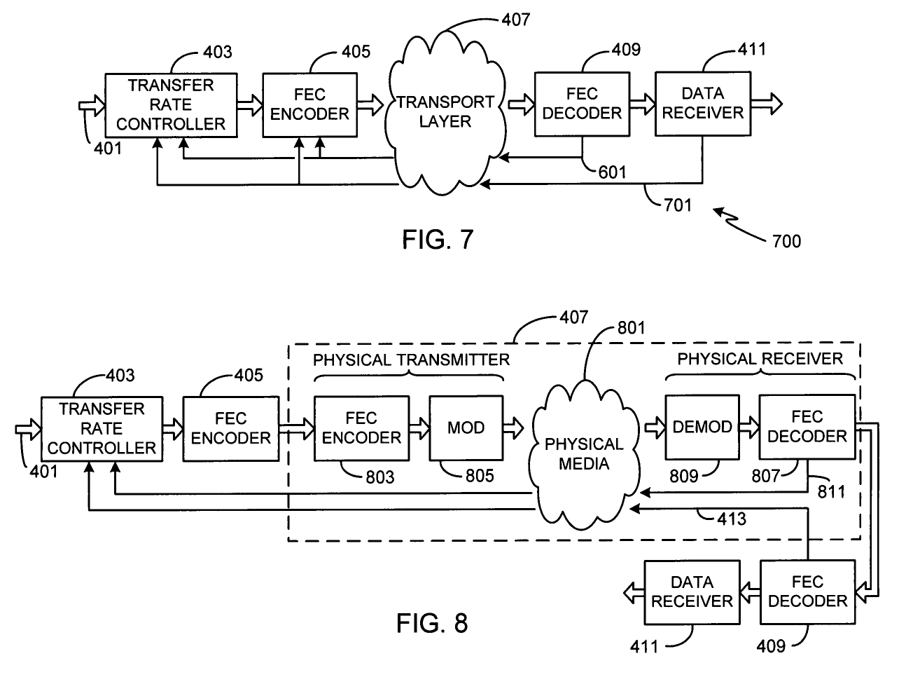

System 700, shown in FIG. 7, illustrates an embodiment of the invention which utilizes both feedback 601 from the FEC decoder 409, and feedback 701 from the data receiver 411. Preferably FEC decoder 409 provides feedback 601 (i.e., FEC performance feedback) both to FEC encoder 405 and transfer rate controller 403 as previously discussed. Similarly, feedback 701 (i.e., error rate feedback) from data receiver 411 is preferably provided to both FEC encoder 405 and transfer rate controller 403.

In the embodiments illustrated and discussed above, preferably the required FEC is an application-layer FEC that is applied, and checked, by the data subsystem which can be used across any channel type.

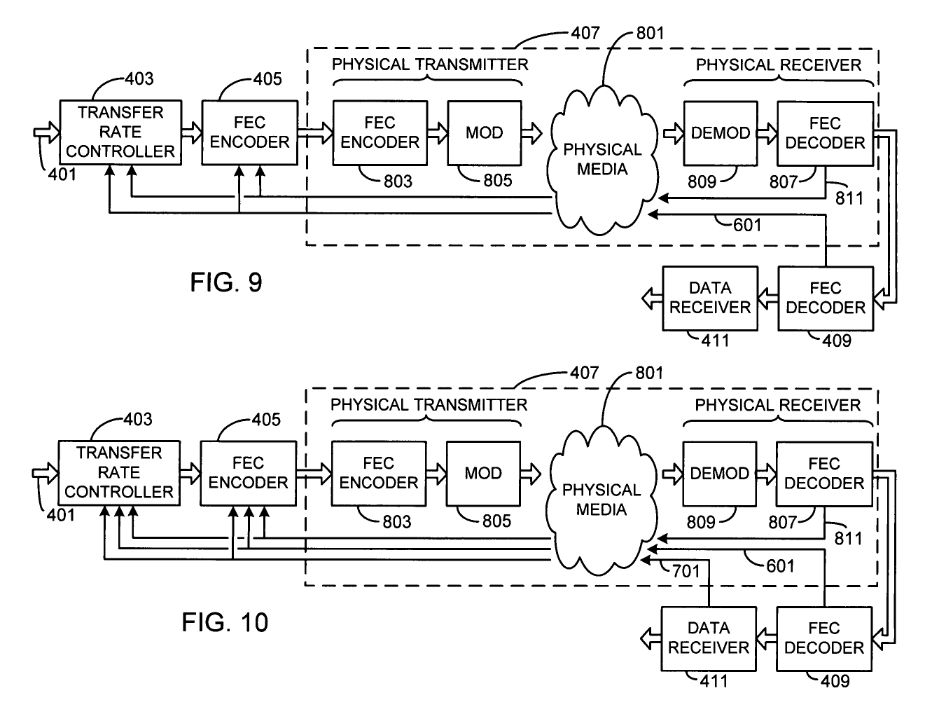

As is well known by those of skill in the art, the last-mile channel or system, which provides the last stretch of data communications into the end-user's home or business (i.e., the final destination for the data), often has much higher error rates than the rest of the network. Consequently this segment will also include one or more FEC encoders/decoders in the physical layer. The embodiments shown in FIGS. 8-10 are based, respectively, on the embodiments shown in FIGS. 4, 6 and 7. Each of these embodiments also includes a physical layer comprised of physical transmitter, a physical receiver, and a physical media 801 (i.e., physical channel/communication link such as twisted pair copper phone wires for DSL or hybrid fiber/coax for cable). The physical transmitter includes at least one FEC encoder 803 and a modulator 805. The physical receiver includes at least one FEC decoder 807 and a demodulator 809. Feedback 811 (i.e., FEC performance feedback) augments feedback 413 from the application layer FEC decoder 409 as shown. Similarly, feedback 811 augments feedback 601 from the application layer FEC decoder 409 as shown in FIG. 9. Similarly, feedback 811 augments feedback 601 and 701 from the application layer FEC decoder 409 and data receiver 411, respectively, as shown in FIG. 10. It should be appreciated that as the physical layer can include cascaded FEC encoders within the physical transmitter and cascaded FEC decoders within the physical receiver, feedback 811 can be from either a single physical layer FEC decoder as shown in FIGS. 8-10, or from multiple cascaded physical layer FEC decoders. Additionally, although not preferred, feedback 811 can be used as the sole FEC feedback for operation of the invention (i.e., elimination of application layer FEC encoder 405, application layer FEC decoder 409, and feedback 413/601).

### EXEMPLARY EMBODIMENT

In a preferred embodiment of the invention, data 401 is comprised of video and/or audio data thereby lending itself to any of a variety of lossy compression techniques (e.g., MPEG-2, MPEG-4, WM-9, MP3, AAC, etc.). Accordingly transfer rate controller 403 is a suitable compressed video encoder (e.g., a trans-coder) or a suitable audio encoder (e.g., a trans-coder) and receiver 411 is a suitable compressed video or audio decoder.

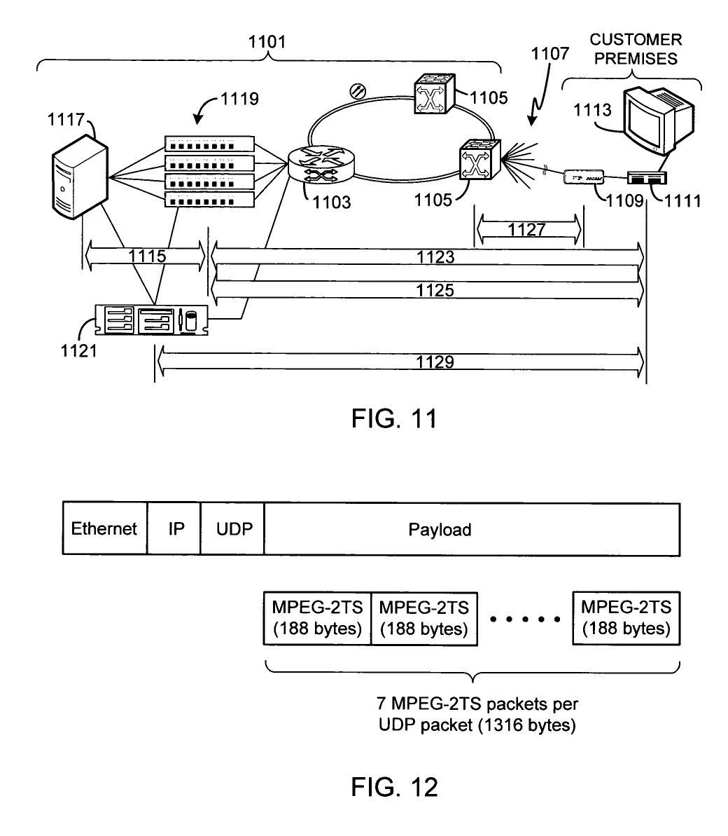

Although it will be appreciated that the invention can utilize any of a variety of well known techniques/devices for controlling the data transfer rate and the exact nature depends both on the type of data and the selected compression technique, FIGS. 11-15 provide one exemplary system. As illustrated, the data transfer system is a video-on-demand system running over a Telco/DSL infrastructure 1101. FIG. 11 is not meant to be all-inclusive, rather it is intended to show the primary components of such a system as well as one implementation of the invention. In this embodiment router 1103, digital subscriber line access multiplexers (DSLAM) 1105, DSL wiring 1107 and DSL modem 1109 make up the channel described in the previous figures (i.e., transport layer 407). At the user site, the system also includes an IP-aware set-top-box (STB) 1111 which provides FEC decoding and performance data feedback. The FEC decoding and performance data feedback functionality can also be provided by a separate, stand-alone device that resides in the data flow prior to STB 1111. The user site also includes a monitor or television 1113.

In this embodiment protocol 1115 between streaming video server 1117 and subsequent device 1119 uses MPEG-2 transport stream (TS) packets, 188 bytes each, encapsulated 7 per UDP frame and carried in UDP/IP frames. In the illustrated embodiment, device 1119 is a digital stream management system such as a Terayon DM 6400 CherryPicker™, preferably under the control of a session manager 1121, device 1119 providing both transfer rate control and FEC encoding functionality. Protocol 1115, shown in detail in FIG. 12, is well known within the digital video industry even though it is not described by an IETF RFC.

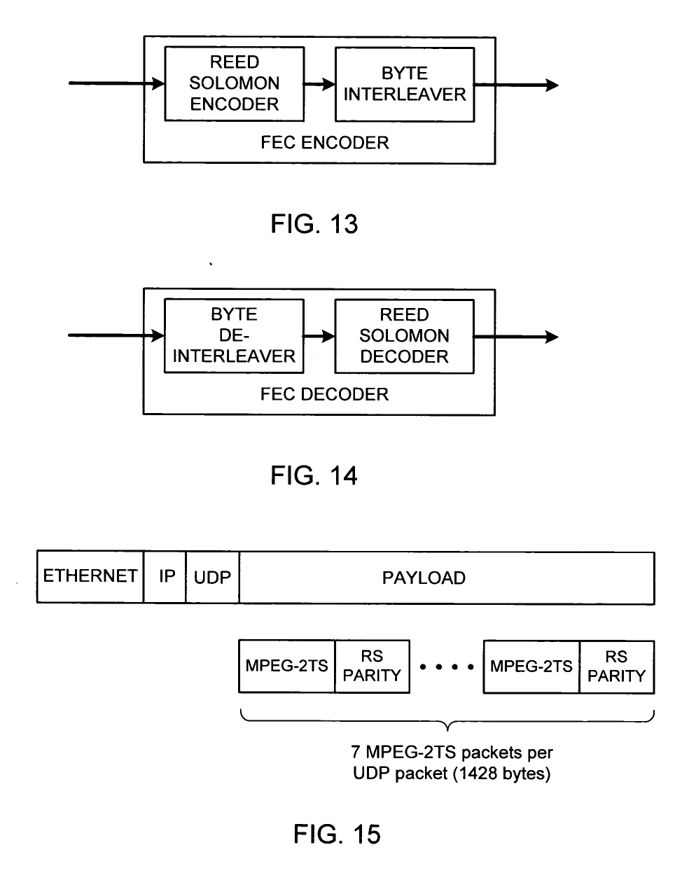

Protocol 1123 is used to transport the FEC-encoded data between the sender and the receiver. Protocol 1123 requires two processing steps on both the encoding and decoding sides as shown in FIGS. 13 and 14, respectively. The first processing step uses an FEC algorithm, for example a Reed-Solomon block FEC algorithm as defined in ITU standard J.83 Annex A. It has a fixed block size with 188 bytes in and 16 bytes of parity, resulting in an output block size of 204 bytes. Thus up to 8 byte errors per block can be corrected. This corresponds to a k of 204 and a T of 8. The resultant packet is illustrated in FIG. 15.

The second processing step of protocol 1123 is an inter-packet byte interleaver. This step is required since Reed-Solomon encoding allows correction of up to T bytes within its codeword. When the DSL channel gets a bit error, the CRC used (see protocol 1127 below) will cause the entire UDP packet to be dropped, resulting in all bytes of all 7 codewords being lost. Accordingly as the FEC algorithm must be able to re-create the entire packet, the data must be spread out preferably such that at most T bytes from any codeword are in any one UDP packet. The interleaver processing step accomplishes this task by interleaving the bytes from a group of source packets in order to create a new group of source packets. Thus the amount of data is unchanged, but it is shuffled (i.e., interleaved) in such a way as to minimize the impact of a lost packet. It will be appreciated that the interleaving process can be performed in a variety of ways.

Rather than using the protocol described above, a standard protocol such as RTP can be used for encapsulating the data such that there are headers with timestamps and/or sequence numbers. This approach will make the discovery of packet loss easier (i.e., the ATM layer will silently discard packets that do not pass CRC check.). It will be appreciated that if a different approach is used, the referenced figures would have to be correspondingly modified, for example adding another small block for packet header generation.

Protocol 1125 is a control protocol that does not carry any of the streaming media, but just includes status information. This is analogous to RTCP, which is part of the RTP protocol (RFC 1889). The purpose of protocol 1125 is for receiver 1111 to report back to sender 1119 on the status of packet reception. Due to the inefficiency of reporting status for each received packet, preferably an adaptive algorithm is used which determines when status information is to be reported back to sender 1119. For example, if no errors are detected then status information would only be reported periodically (e.g., every few seconds). If errors are detected, then status feedback would be provided immediately.

Protocol 1127, shown for completeness, illustrates that there is a level of error checking that happens below the communication protocols used for the invention. DSL systems are typically ATM based and use ATM AAL5 encapsulation to carry all IP packet payloads. This protocol has a 32-bit CRC in a data trailer so that the receiver (i.e., modem 1109 in this example) can check the data for errors. Packets with any bit errors are dropped. As a result, with this type of link-layer protocol a single bit error is turned into a complete packet loss. Therefore the FEC algorithm used in the invention must be able to re-create entire lost packets, not just patch a few wrong bits.

Protocol 1129 is a real-time streaming protocol (RTSP) that is used by IP STB 1111 to request and control video playback. This protocol is not important relative to the invention and is included only for the sake of completeness.

As previously noted, the implementation described above and illustrated in FIGS. 11-15 is only one possible implementation of an embodiment of the invention. Regardless of the embodiment, the data is FEC encoded prior to being sent over the transport layer (i.e., communication link) and then decoded, the FEC decoder providing feedback to the transfer rate controller regarding the quality of the link, thus allowing the controller to adjust the transfer rate. It will be appreciated that there are many ways in which the invention can be implemented without departing from the key aspects of the invention. A few of the variations include:
FEC Algorithm—The Reed-Solomon FEC with interleaving is a reasonable FEC, but there are many others that could be used equally well. Examples of other algorithms include; (i) low density parity check (LDPC), (ii) low density generator matrix (LDGM), (iii) Bose-Chaudhuri-Hochquenghem (BCH) codes, (iv) turbo codes, and (v) convolutional codes. The critical requirement for an FEC algorithm is that the decoding process provides a status indicating the results in terms of non-corrected, FEC-correctable and FEC-uncorrectable data.
Interleaving—The system described relative to FIGS. 11-15 uses a link layer that drops packets with any bit errors. In such a system the FEC must be able to re-construct a packet by including redundant information in other packets. With the small block Reed-Solomon FEC code used in the example, interleaving is needed. With other FEC methods, interleaving may not be needed to accomplish this task. If the link layer does not drop packets with bit errors, there are more options for the FEC algorithms since small errors within a single packet could be corrected.
Data Transfer Rate Control—There are a variety of well known techniques for varying the transfer rate of the data, all of which can be used with the invention.
Invention Applicability—As previously noted, the present invention is not limited to the Internet, but can be used with any of a variety of other network technologies, e.g., wireless networks, satellite based systems, etc. Additionally, the present invention is not limited to a particular link layer technology, e.g., DSL, cable-TV/Native-MPEG, Cable-TV/Docsis, etc.
Transport Protocol—The invention is applicable to any transport protocol.
Video Encoding—The invention can be used with any video encoding scheme that supports varying the rate of the video stream, e.g., MPEG-2, MPEG-4 (also referred to as H.264 or AVC), WM-9 (also referred to as SMPTE VC-1), etc.
FEC Feedback Protocol—Although the use of FEC feedback is critical to the invention, any of a variety of protocols could be used equally well to convey this feedback back to the source.

As will be understood by those familiar with the art, the present invention may be embodied in other specific forms without departing from the spirit or essential characteristics thereof. Some possible variations are described above. Accordingly, the disclosures and descriptions herein are intended to be illustrative, but not limiting, of the scope of the invention which is set forth in the following claims.

What is claimed is:

1. A system for adjusting a data transfer rate, the apparatus comprising:
a source of data;
a transfer rate controller coupled to said source of data and outputting a data stream with a first transfer rate;
a forward error correction (FEC) encoder coupled to said transfer rate controller, said FEC encoder applying an FEC algorithm to said data stream;
a communication link coupled to said FEC encoder, wherein said encoded data stream is transmitted over said communication link after application of said FEC algorithm by said FEC encoder;
an FEC decoder coupled to said communication link and receiving said encoded data stream, said FEC decoder providing feedback to said transfer rate controller regarding communication link quality, wherein said transfer rate controller adjusts said first transfer rate in response to said feedback; and
a receiver coupled to said FEC decoder, said receiver outputting a decoded data stream.

2. The system of claim 1, wherein said transfer rate controller further comprises a rate shaper.

3. The system of claim 1, wherein said FEC decoder corrects at least a portion of any data lost in transit.

4. The system of claim 1, wherein said FEC decoder provides a secondary feedback to said FEC encoder, and wherein said FEC encoder adjusts said FEC algorithm in response to said secondary feedback.

5. The system of claim 1, wherein said receiver provides a secondary feedback to said transfer rate controller, and wherein said transfer rate controller adjusts said first transfer rate in response to said secondary feedback.

6. The system of claim 1, wherein said receiver provides a secondary feedback to said FEC encoder, and wherein said FEC encoder adjusts said FEC algorithm in response to said secondary feedback.

7. The system of claim 1, further comprising a physical layer, said physical layer comprising:
a modulator, said modulator including a second FEC encoder, said second FEC encoder applying a second FEC algorithm to said encoded data stream;
a second communication link coupled to said second FEC encoder; and
a second FEC decoder coupled to said second communication link, said second FEC decoder providing secondary feedback to said transfer rate controller regarding secondary data transfer channel quality, wherein said transfer rate controller adjusts said first data transfer rate in response to said secondary feedback.

8. A system for adjusting a data transfer rate, the apparatus comprising:
a source of data, said data selected from the group consisting of video data and audio data;
a data encoder coupled to said source of data and outputting an encoded data stream of a first transfer rate;
a forward error correction (FEC) encoder coupled to said transfer rate controller, said FEC encoder applying an FEC algorithm to said encoded data stream;
a communication link coupled to said FEC encoder, wherein said encoded data stream is transmitted over said communication link after application of said FEC algorithm by said FEC encoder;
an FEC decoder coupled to said communication link and receiving said encoded data stream, said FEC decoder providing feedback to said data encoder regarding communication link quality, wherein said data encoder adjusts said first transfer rate in response to said feedback; and
a compressed video decoder coupled to said FEC decoder, said compressed video decoder outputting a decoded data stream.

9. The system of claim 8, wherein said data encoder is a trans-coder.

10. The system of claim 8, wherein said FEC decoder corrects at least a portion of any data lost in transit.

11. The system of claim 8, wherein said FEC decoder provides a secondary feedback to said FEC encoder, and wherein said FEC encoder adjusts said FEC algorithm in response to said secondary feedback.

12. The system of claim 8, wherein said compressed video decoder provides a secondary feedback to said data encoder, and wherein said data encoder adjusts said first transfer rate in response to said secondary feedback.

13. The system of claim 8, wherein said compressed video decoder provides a secondary feedback to said FEC encoder, and wherein said FEC encoder adjusts said FEC algorithm in response to said secondary feedback.

14. The system of claim 8, further comprising a physical layer, said physical layer comprising:
a modulator, said modulator including a second FEC encoder, said second FEC encoder applying a second FEC algorithm to said encoded data stream;
a second communication link coupled to said second FEC encoder; and
a second FEC decoder coupled to said second communication link, said second FEC decoder providing secondary feedback to said data encoder regarding secondary data transfer channel quality, wherein said data encoder adjusts said first data transfer rate in response to said secondary feedback.

15. A method of optimizing a data transfer rate of data from a source to a destination over a communication link, the method comprising the steps of:
setting a first data transfer rate for transferring said data;
encoding said data with an FEC encoder;
transferring said data over said communication link;
decoding said data with an FEC decoder to determine a quality characteristic of said data transferred over said communication link;
generating a feedback message with said FEC decoder, said feedback message corresponding to said quality characteristic;
adjusting said data transfer rate from said first data transfer rate to a second data transfer rate in response to said feedback message; and
forwarding said data to a receiver.

16. The method of claim 15, wherein said first data transfer rate setting step further comprises the step of encoding said data, and wherein said method further comprises the step of decoding said data after said data forwarding step.

17. The method of claim 15, wherein said first data transfer rate setting step further comprises the step of applying a rate shaper to said data.

18. The method of claim 15, wherein said quality characteristic determining step comprises the steps of determining error occurrence and error magnitude in said data transferred over said communication link.

19. The method of claim 15, further comprising the step of correcting errors of at least a first type within said data transferred over said communication link.

20. The method of claim 15, wherein said error correcting step is performed before said quality characteristic determining step.

21. The method of claim 15, further comprising the step of adjusting said FEC algorithm in response to said feedback message.

22. The method of claim 15, further comprising the step of generating a second feedback message after said data forwarding step.

23. The method of claim 22, further comprising the step of adjusting said data transfer rate from said second data transfer rate to a third data transfer rate in response to said second feedback message.

24. The method of claim 22, further comprising the step of adjusting said FEC algorithm in response to said second feedback message.

25. The method of claim 15, further comprising the steps of:
applying a second FEC algorithm to said data prior to said quality characteristic determining step;
transferring said data over a second communication link;
determining a second quality characteristic of said data transferred over said second communication link; and
generating a second feedback message corresponding to said second quality characteristic, wherein said data transfer rate adjusting step adjusts said data transfer rate from said first data transfer rate to said second data transfer rate in response to said feedback message and said second feedback message.
